(19) United States
(12) Patent Application Publication
(10) Pub. No.: US 2014/0225593 A1
(43) Pub. Date: Aug. 14, 2014

(54) CURRENT DETECTION DEVICE

(71) Applicants: Hirokatsu Nakajima, Yokkaichi (JP); Satoru Chaen, Yokkaichi (JP); Shunji Taga, Yokkaichi (JP)

(72) Inventors: Hirokatsu Nakajima, Yokkaichi (JP); Satoru Chaen, Yokkaichi (JP); Shunji Taga, Yokkaichi (JP)

(73) Assignee: SUMITOMO WIRING SYSTEMS, LTD., Yokkaichi, Mie (JP)

(21) Appl. No.: 14/128,384

(22) PCT Filed: Feb. 2, 2012
(86) PCT No.: PCT/JP2012/052340

§ 371 Date: Feb. 25, 2014

(30) Foreign Application Priority Data
Jul. 5, 2011 (JP) 2011-148840

(51) Int. Cl. G01R 15/20

(52) U.S. Cl. CPC G01R 15/20
USPC 324/117 R

(57) ABSTRACT

A current detector for detecting a current that flows through a busbar is provided. A current detector includes a magnetic core, a current detection busbar, and an insulating casing. The current detection busbar is composed of a member obtained by shaping both end portions of a rod-shaped conductor that penetrates the insulating casing and the hole portion of the magnetic core so that the two end portions are wider than an intermediate portion between the two end portions. The two shaped end portions form two terminal portions that are respectively to be joined to other upstream and downstream busbars. The insulating casing has busbar holes that are formed in a shape conforming to the contour of the intermediate portion of the current detection busbar and penetrated by the intermediate portion.

This application is the national phase of PCT International Application No. PCT/JP2012/052340 that has an International filing date of Feb. 2, 2012 and designated the United States of America and claims priority to Japanese Patent App. No. JP 2011-148840 that was filed on Jul. 5, 2011. The disclosure of the prior applications is hereby incorporated by reference herein in their entirety.

### BACKGROUND

Vehicles such as hybrid automobiles or electric automobiles in many cases include a current detector for detecting a current that flows through a busbar connected to a battery. Examples of apparatuses that may be applied as such a current detector include a magnetic proportion-type current detector and a magnetic balance-type current detector.

A current detector of a magnetic proportion type or a magnetic balance type includes a magnetic core and a magneto-electric conversion element, for example, as shown in JP H10-104279A, JP 2006-166528A, and JP 2009-58451A. The magnetic core is a magnetic material substantially in the shape of a ring with a gap portion, resulting in two ends facing each other across the gap portion, and formed in one piece so as to surround a hole portion penetrated by a busbar. The hole portion of the magnetic material is a space (current detection space) through which a current that is to be detected flows.

Furthermore, the magneto-electric conversion element is disposed in the gap portion of the magnetic core. The magneto-electric conversion element is an element that detects a magnetic flux that changes in accordance with a current that flows through the busbar penetrating the hole portion, and then outputs a detection signal of the magnetic flux as an electrical signal. As the magneto-electric conversion element, typically, a Hall element is used.

As disclosed in JP 2009-58451A, in current detectors, the magnetic core and the magneto-electric conversion element are often held in a fixed positional relationship by an insulating casing. The casing positions a plurality of components constituting a current detector in a fixed positional relationship. Note that generally the casing is composed of an insulating resin member.

Often, a supporting portion that positions the magnetic core is formed in the casing. For example, in the current detector disclosed in JP 2009-58451A, the supporting portion for the magnetic core is recessed portions of the casing that respectively have shapes conforming to an outer circumferential surface and an inner circumferential surface of the magnetic core. Furthermore, through holes through which the busbar passes are formed in the casing of the current detector.

### SUMMARY

### Technical Problem

In certain current detectors for a battery of a vehicle, since a flat plate-like busbar is inserted into a hole portion of a magnetic core, the magnetic core needs to be configured such that the maximum width (diameter) of the hole portion is larger than the width of the busbar. However, electric automobiles, hybrid automobiles, and the like employ more and more a wide busbar in order to prevent the busbar from excessively generating heat associated with an increase in a current that flows through the busbar.

Accordingly, a current detector may have a problem that the wider the busbar is, the larger the magnetic core is required in proportion to the width of the busbar, and the larger the casing is required that houses the magnetic core, leading to a larger space in which the current detector is installed. In particular, in the case where the magnetic core is in the shape of a circular ring, an elliptical ring, or a rectangular ring in which the ratio of the longitudinal length to the lateral length is 1 or approximately 1, a wasted space in the hole portion of the magnetic core increases as the width of the busbar increases. Also, in the case where a busbar in which only a portion that is to be disposed in the hole portion of the magnetic core is narrowed is employed, a problem may occur that heat is excessively generated at the narrowed portion.

It is an object to provide a current detector for detecting a current that flows through a busbar, in which it is possible to achieve both downsizing of the current detector by employing a relatively small magnetic core in relation to the size of conductors that are arranged upstream and downstream of the current detector in a current transmission path, and prevention of the busbar from excessively generating heat.

### Solution to Problem

A current detector for detecting a current that flows through a busbar including the following constituent components: (1) a first constituent component is a magnetic core that is formed in one piece so as to surround a hole portion penetrated by the busbar, two ends of the magnetic core facing each other across a gap portion; (2) a second constituent component is a magneto-electric conversion element that is disposed in the gap portion of the magnetic core and detects a magnetic flux that changes in accordance with a current that passes through the hole portion of the magnetic core; (3) a third constituent component is a current detection busbar that is composed of a member obtained by shaping both end portions of a rod-shaped conductor that penetrates the hole portion of the magnetic core, the two end portions occupying certain ranges from respective ends of the conductor, so that the two end portions are wider than an intermediate portion between the two end portions, the two shaped end portions of this current detection busbar forming two terminal portions that are to be joined to an upstream connection end and a downstream connection end, respectively, in a current transmission path; and (4) a fourth constitutional element is a casing that supports and houses a portion of the intermediate portion of the current detection busbar, the magnetic core, and the magneto-electric conversion element in a fixed positional relationship and has busbar holes that are formed in a shape conforming to the contour of the intermediate portion of the current detection busbar and with a smaller width than the width of the terminal portions and penetrated by the intermediate portion.

In the current detector, it is conceivable that the casing includes a core supporting portion that is formed on an internal side face of the casing, protruding from an edge portion of the busbar hole. The core supporting portion supports the magnetic core by being inserted in the hole portion of the magnetic core and also supports the current detection busbar in a state in which the core supporting portion is sandwiched between the magnetic core and the intermediate portion of the current detection busbar.

In the current detector, a projecting portion is formed on a face of the core supporting portion that faces the current detection busbar or the magnetic core, the projecting portion being plastically deformable under pressure applied by the magnetic core and the intermediate portion of the current detection busbar sandwiching the projecting portion.

In the current detector, it is conceivable that the intermediate portion of the current detection busbar has a contour shape that is homothetically similar to the contour shape of the hole portion of the magnetic core.

In the current detector, it is conceivable that the intermediate portion of the current detection busbar has a cylindrical shape.

In the current detector, it is conceivable that the terminal portions of the current detection busbar are portions that are shaped by performing press working of the two end portions of the rod-shaped metal member so that the two end portions have a flat plate-like shape that is wider than other portions of the rod-shaped metal member.

In the current detector, it also is conceivable that the terminal portions of the current detection busbar are portions that are shaped by performing upsetting of the two end portions of the rod-shaped metal member so that the two end portions are thicker than other portions of the rod-shaped metal member.

### Advantageous Effects

In the current detector, the two end portions of the current detection busbar serve as the terminal portions that are respectively to be joined to connection ends of upstream and downstream conductors in the current transmission path. Moreover, the busbar holes of the easing are formed in a shape that conforms to the contour of the intermediate portion of the current detection busbar. Furthermore, the two terminal portions of the current detection busbar are formed in conformity with the width of the upstream and downstream conductors so that the width (thickness) of the two terminal portions is larger than the width (thickness) of the intermediate portion that penetrates the busbar holes of the casing and the hole portion of the magnetic core.

That is to say, at least one of the two terminal portions of the current detection busbar is obtained by shaping the corresponding end portion of the rod-shaped conductor after passing the rod-shaped conductor through the busbar holes of the casing and the hole portion of the magnetic core. Therefore, it is possible to downsize the current detector by employing a magnetic core that is relatively small in relation to the size of the upstream and downstream conductors in the current transmission path.

Moreover, in the current detection busbar, the intermediate portion that penetrates the busbar holes of the casing and the hole portion of the magnetic core has the shape of a rod, such as a round bar or a square bar, in which the ratio of the width to the thickness is 1 or approximately 1. Thus, this intermediate portion can be configured so as to have a larger cross-sectional area than that of a flat plate-like busbar, with the restriction that the maximum width of the intermediate portion is smaller than the width of the hole portion of the magnetic core. Therefore, even in the case where a relatively small magnetic core is employed, it is possible to prevent the current detection busbar from excessively generating heat.

Moreover, in the current detector, it is preferable that the core supporting portion supports the magnetic core and the current detection busbar in a state in which the core supporting portion is sandwiched between the magnetic core and the current detection busbar. In this case, even if the core supporting portion is provided in a state in which a little gap (play) is created between the core supporting portion and the magnetic core, when the core supporting portion is inserted between the magnetic core and the intermediate portion of the current detection busbar in the hole portion of the magnetic core, the core supporting portion elastically deforms under pressure applied by the current detection busbar and comes into close contact with the inner circumferential surface of the magnetic core. Thus, a phenomenon in which the magnetic core and the core supporting portion repeatedly collide with each other in an environment in which the magnetic core and the core supporting portion are subjected to vibrations of the vehicle or the like does not occur, and the magnetic core and the core supporting portion are unlikely to wear down due to the vibrations.

Moreover, if the projecting portion that is formed on the core supporting portion plastically deforms under pressure applied by the magnetic core and the intermediate portion of the current detection busbar sandwiching the projecting portion, the dimensional tolerances of the current detection busbar, the core supporting portion, and the magnetic core are accommodated by the extent of the plastic deformation of the projecting portion. Thus, it is possible to avoid a situation in which the core supporting portion cannot be inserted into a gap between the magnetic core and the current detection busbar due to the dimensional tolerances.

Moreover, if the contour shape of the intermediate portion of the current detection busbar is homothetically similar to the contour shape of the hole portion of the magnetic core, the gap between the current detection busbar and the magnetic core can be made smaller. As a result, it is possible to downsize the current detector by employing a smaller magnetic core.

Moreover, if the intermediate portion of the current detection busbar has a cylindrical shape, and the busbar holes have a circular shape, the casing can be rotated around the intermediate portion of the current detection busbar. In this case, in a state in which the two terminal portions of the current detection busbar are respectively fixed to the other upstream and downstream busbars, the overall orientation of the casing and the constitutional elements that are supported by the casing except the current detection busbar can be changed. Therefore, the degree of freedom of attachment of the current detector is increased.

Moreover, the terminal portions of the current detection busbar can be easily made by, for example, press working or upsetting of the rod-shaped metal member.

### BRIEF DESCRIPTION OF THE DRAWINGS

FIG. 1 shows an exploded perspective view of a current detector 1 according to an embodiment.

FIG. 2 shows an exploded perspective view of the current detector 1.

FIG. 3 shows a front view of a casing main body of an insulating casing included in the current detector 1.

FIG. 4 shows a plan view of the current detector 1.

FIG. 5 shows a cross-sectional view of the current detector 1 as seen from a current flow direction.

FIG. 6 shows a cross-sectional view of the current detector 1 as seen from a direction that is orthogonal to the current flow direction.

FIG. 7 shows a perspective view of a step of performing press working of a member that mainly constitutes a current detection busbar included in the current detector 1.

FIG. 8 shows a front view of the current detector 1 fixed to a terminal block.

FIG. 9 shows a perspective view of a current detection busbar according to a modification that is applicable to the current detector 1, and the magnetic core.

### DETAILED DESCRIPTION OF THE EMBODIMENTS

Hereinafter, an embodiment will be described with reference to the appended drawings. The following embodiment is merely a specific example of the invention, and is not to restrict the technical scope of the invention.

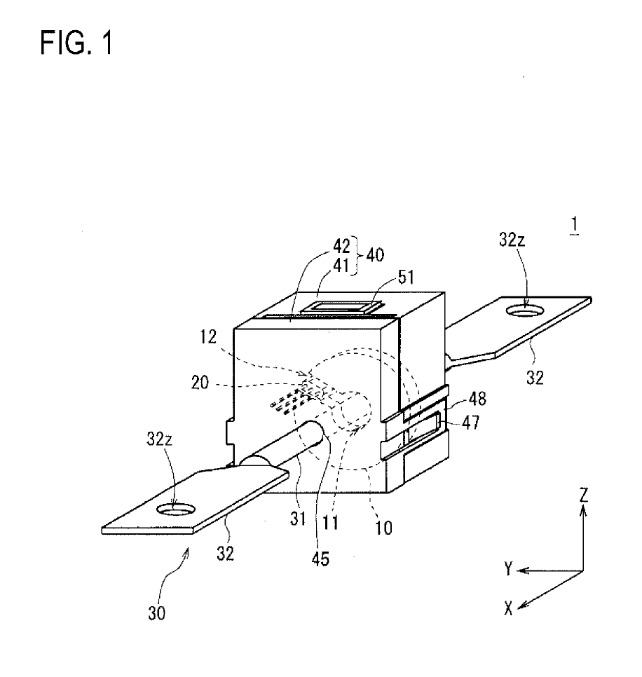

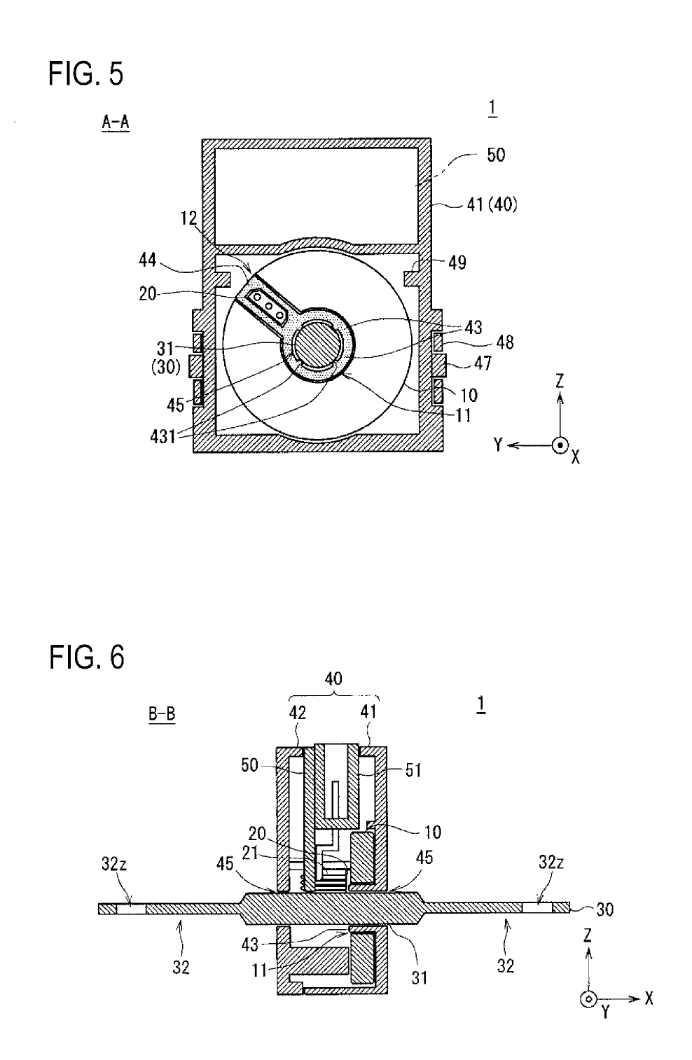

Hereinafter, the configuration of a current detector 1 according to an embodiment will be described with reference to FIGS. 1 to 6. The current detector 1 is an apparatus for detecting a current that flows through a busbar electrically connecting a battery and a device such as a motor, in a vehicle such as an electric automobile, a hybrid automobile, or the like. Note that FIG. 5 is a cross-sectional view taken along plane A-A of a plan view shown in FIG. 4, and FIG. 6 is a cross-sectional view taken along plane B-B of the plan view shown in FIG. 4.

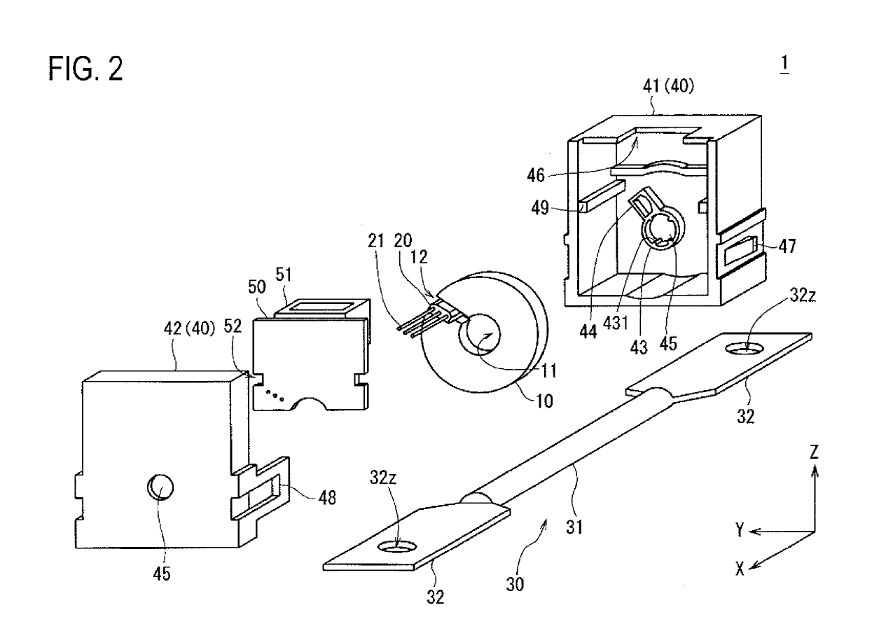

As shown in FIG. 2, the current detector 1 includes a magnetic core 10, a Hall element 20, a current detection busbar 30, an insulating casing 40, and an electronic circuit board 50. Note that in FIG. 1, principal constitutional elements housed in the insulating casing 40 are indicated by dashed lines.

<Magnetic Core>

The magnetic core 10, which is a magnetic material made from ferrite, silicon steel, or the like, is in a shape that has both of its two ends facing each other across a gap portion 12 with a size of approximately several millimeters, and is formed in one piece so as to surround a hole portion 11. That is to say, the magnetic core 10 is formed in the shape of a ring in conjunction with the narrow gap portion 12. The magnetic core 10 in this embodiment is in the shape of a circular ring that surrounds the circular hole portion 11 in conjunction with the gap portion 12.

<Hall Element (Magneto-Electric Conversion Element)>

The Hall element 20 is disposed in the gap portion 12 of the magnetic core 10. The Hall element 20 is an example of a magneto-electric conversion element for detecting a magnetic flux that changes in accordance with a current that passes through the hole portion 11 of the magnetic core 10, and then outputting a detection signal of the magnetic flux as an electrical signal. In this embodiment, the Hall element 20 is a lead wire-type IC that has lead wires 21 extending from a main body portion. The lead wires 21 include a lead wire for inputting electric power and a lead wire for outputting a detection signal. It also is conceivable that the Hall element 20 is a surface mount IC.

The Hall element 20 is disposed so that a detection center point that is defined in the main body portion in advance is located at a center point of the gap portion 12 of the magnetic core 10, and the front and back surfaces of the main body portion are orthogonal to the direction of the magnetic flux that is formed in the gap portion 12. In an ideally disposed state, the Hall element 20 is in a state in which its detection center point is located on a line connecting the centers of planes of projection of the two end portions of the magnetic core 10 that face each other.

<Electronic Circuit Board>

The electronic circuit board 50 is a printed circuit board on which the portions of the lead wires 21 of the Hall element 20 are mounted. In addition to the Hall element 20, a circuit that performs processing, for example, amplification of the detection signal of the magnetic flux output from the Hall element 20 and a connector 51 are mounted on the electronic circuit board 50.

The connector 51 is a component to which a counterpart connector that is provided on a wire, which is not shown, is connectable. Furthermore, the electronic circuit board 50 is equipped with circuits for electrically connecting the lead wires 21 of the Hall element 20 to terminals of the connector 51. For example, the electronic circuit board 50 is equipped with a circuit for supplying power that is input from the outside via the wire and the connector 51 to the lead wire 21 of the Hall element 20, a circuit for amplifying the detection signal of the Hall element 20 and outputting the amplified signal to the terminal of the connector 51, and the like. Thus, the current detector 1 can output a current detection signal to an external circuit such as an electronic control unit through the wire with the connector that is connected to the connector 51.

<Current Detection Busbar>

The current detection busbar 30 is a conductive member made of a metal such as copper, and functions as part of a set of busbars electrically connecting a battery and an electrical device. That is to say, a current that is to be detected flows through the current detection busbar 30. Furthermore, the current detection busbar 30 is a member independent of a battery-side busbar that is connected in advance to the battery and a device-side busbar that is connected in advance to the electrical device. Both ends of the current detection busbar 30 are respectively connected to the other pre-installed busbars (the battery-side busbar and the device-side busbar).

As shown in FIGS. 1, 2, 4, and 6, the current detection busbar 30 is composed of a member obtained by shaping both end portions of a rod-shaped conductor that penetrates the hole portion 11 of the magnetic core 10 so that the two end portions are wider than an intermediate portion 31 between the two end portions. Note that the two end portions of the rod-shaped conductor are portions that occupy certain ranges from respective ends of the rod-shaped conductor.

The two end portions of the current detection busbar 30, which are shaped so as to be wider than the intermediate portion 31, serve as two terminal portions 32 that are respectively to be joined to upstream and downstream connection ends in a current transmission path. The current detection busbar 30 is a member substantially made of a conductor that includes the rod-shaped intermediate portion 31 that occupies a certain range at the center. The two terminal portions 32 that are formed so as to extend from the opposite sides of the intermediate portion 31.

The intermediate portion 31 is a portion that penetrates busbar holes 45, which are through holes formed in the insulating casing 40, and the hole portion 11 of the magnetic core 10 in the current flow direction. The current flow direction is the thickness direction of the magnetic core 10, is the axial direction of a cylinder when taking the ring-like magnetic core 10 as a cylinder, and is the direction orthogonal to a plane formed by the ring-like magnetic core 10. In the drawings, the current flow direction is indicated as the X-axis direction.

In the current detection busbar 30 of this embodiment, the intermediate portion 31 has a cylindrical shape, and the terminal portions 32 have a flat plate-like shape. Moreover, in this embodiment, since the hole portion I 1 of the magnetic core 10 has a circular shape, the contour shape of the intermediate portion 31 of the current detection busbar 30 is homothetically similar to the contour shape of the hole portion of the magnetic core 10. In the drawings, the width direction and the thickness direction of the flat plate-like terminal portions 32 are indicated as the Y-axis direction and the Z-axis direction, respectively.

In this embodiment, each of the two flat plate-like terminal portions 32 of the current detection busbar 30 has a screw through hole 32z into which a screw is inserted. The two terminal portions 32 are joined to the other upstream and downstream flat plate-like busbars via screws.

Note that it also is conceivable that the two terminal portions 32 of the current detection busbar 30 do not have the through holes 32z. In this case, the two terminal portions 32 may be joined to the other upstream and downstream busbars by crimping, spot welding, or the like.

The current detection busbar 30 is a member that has a structure in which the two end portions, which occupy certain ranges from the respective ends of the rod-shaped metal member, are shaped into a flat plate-like shape by press working using a pressing machine or the like. However, in the current detector 1, it is not possible to pass the current detection busbar 30 in which the two flat plate-like terminal portions 32 have been formed through the busbar holes 45 of the insulating casing 40. Procedures for attaching the current detection busbar 30 to the insulating casing 40 will be described later.

<Insulating Casing>

The insulating casing 40 is an insulating member that holds and supports the magnetic core 10, the current detection busbar 30, and the electronic circuit board 50 on which the Hall element 20 and the connector 51 are mounted in a fixed positional relationship. The insulating casing 40 includes two members, namely, a casing main body 41 and a cover member 42 that is attached to the casing main body 41. The casing main body 41 and the cover member 42 are, for example, each a monolithic molded member made of insulating resin such as polyamide (PA), polypropylene (PP), or ABS resin.

The casing main body 41 is in the shape of a box having an opening portion, and the cover member 42 covers the opening portion of the casing main body 41 when attached to the casing main body 41. Also, the casing main body 41 and the cover member 42 have the busbar holes 45, which are the through holes penetrated by the intermediate portion 31 of the current detection busbar 30.

As shown in FIGS. 1, 2, 3, and 5, each of the busbar holes 45 is formed in a shape that conforms to the contour of the intermediate portion 31 of the current detection busbar 30. Accordingly, the width (diameter) of the busbar holes 45 is smaller than the width of the two terminal portions 32 of the current detection busbar 30. Thus, it is not possible to pass the current detection busbar 30 in which the two flat plate-like terminal portions 32 have been formed through the busbar holes 45 of the insulating casing 40. The procedures for attaching the current detection busbar 30 to the insulating casing 40 will be described later.

Note that since the busbar holes 45 are formed in the shape that conforms to the contour of the intermediate portion 31 of the current detection busbar 30, the contour shape of the busbar holes 45 is homothetically similar to the contour shape of the intermediate portion 31 of the current detection busbar 30.

In this embodiment, the intermediate portion 31 of the current detection busbar 30 has a cylindrical shape, and the busbar holes 45 are formed in a circular shape that conforms to the circumferential surface of the intermediate portion 31. Thus, it is possible to rotate the insulating casing 40 around the intermediate portion 31 of the current detection busbar 30 in a state in which the current detection busbar 30 penetrates the insulating casing 40.

Furthermore, the cover member 42 is attached to the casing main body 41 holding the magnetic core 10, the Hall element 20, and the current detection busbar 30 such that the cover member 42 covers the opening portion of the casing main body 41 while sandwiching the magnetic core 10 and the electronic circuit board 50 including the connector 51 therebetween.

FIGS. 1 and 4 show a perspective view and a plan view, respectively, of the current detector 1 in a state in which the casing main body 41 and the cover member 42 are combined with each other. As shown in FIGS. 1 and 4, the casing main body 41 and the cover member 42 (the insulating casing 40) support the magnetic core 10, the Hall element 20, and the current detection busbar 30 in the fixed positional relationship while sandwiching the magnetic core 10 and the electronic circuit board 50 therebetween in a state in which specific portions of the intermediate portion 31 and the terminal portions 32 of the current detection busbar 30 as well as the connector 51 of the electronic circuit board 50 are exposed to the outside.

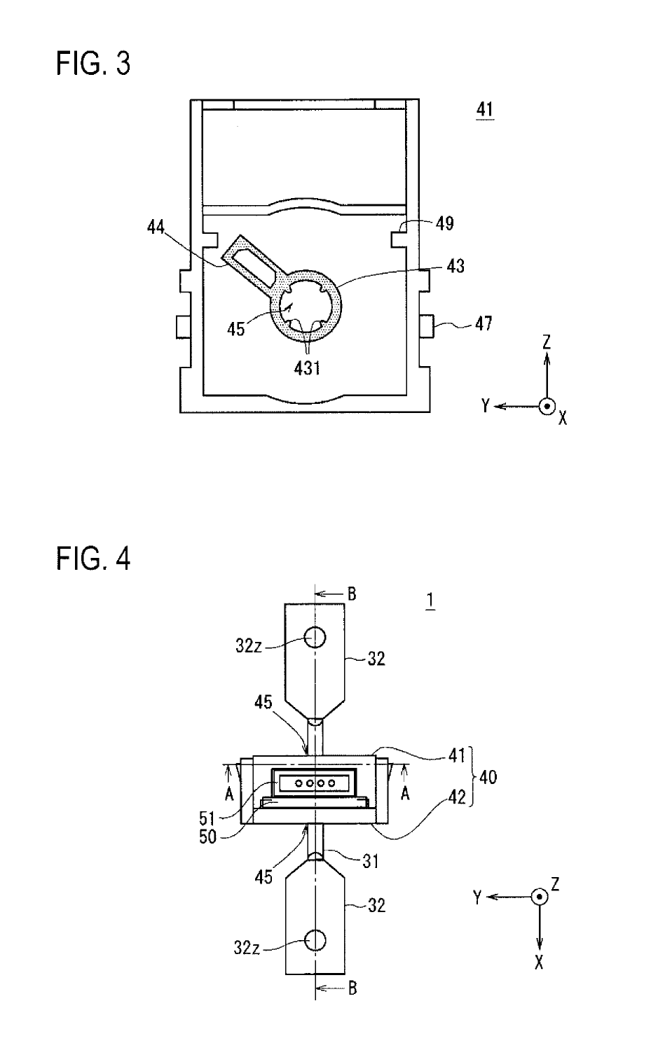

More specifically, the positions of the magnetic core 10 and the Hall element 20 within the insulating casing 40 in a direction that is parallel to a plane (X-Z plane) that is orthogonal to the current flow direction (X-axis direction) are held by a core supporting portion 43 and an element supporting portion 44. Note that in FIGS. 3 and 5, portions corresponding to the core supporting portion 43 and the element supporting portion 44 are indicated by a dot pattern.

Furthermore, the position of the magnetic core 10 in the current flow direction (X-axis direction) is held by the magnetic core 10 being sandwiched between the casing main body 41 and the cover member 42. Similarly, the position of the Hall element 20 that is secured to the electronic circuit board 50 in the current flow direction (X-axis direction) is held by the electronic circuit board 50 being sandwiched between the casing main body 41 and the cover member 42.

Moreover, as shown in FIGS. 1, 3, and 5, a circuit board supporting portion 49 is formed so as to protrude from an internal side face of a side wall of the casing main body 41. The circuit board supporting portion 49 is fitted to a cut-out portion 52 that is formed in the electronic circuit board 50, and supports the electronic circuit board 50 in a predetermined position.

Furthermore, the casing main body 41 and the cover member 42 are provided with lock mechanisms 47 and 48 that hold the casing main body 41 and the cover member 42 in a state in which they are combined with each other. The lock mechanisms 47 and 48 shown in FIG. 1 are respectively configured as a catch portion 47 that is formed so as to project from a side face of the casing main body 41 and a ring-shaped frame portion 48 that is formed on a side face of the cover member 42. When the catch portion 47 of the casing main body 41 is fitted to the hole defined by the frame portion 48 of the cover member 42, the casing main body 41 and the cover member 42 are held in a state in which they are combined with each other.

Hereinafter, with reference to FIGS. 2, 3, 5, and 6, the structure by which the casing main body 41 supports the magnetic core 10 and the Hall element 20 will be described.

As shown in FIGS. 2 and 3, the core supporting portion 43 and the element supporting portion 44 that protrude in the current flow direction (X-axis direction) are formed on an internal side face of the casing main body 41, which is one of the two members constituting the insulating casing 40.

The core supporting portion 43 protrudes from the internal side face of the casing main body 41 along an edge portion of the busbar hole 45 and has a tubular shape. In this embodiment, since the busbar holes 45 have a circular shape, the core supporting portion 43 is formed in a cylindrical tube-like shape. Note that it also is conceivable that a plurality of core supporting portions 43 are formed on the internal side face of the casing main body 41 along the edge portion of the busbar hole 45 in such a manner that one faces another.

The internal side face of the core supporting portion 43, which is a face that faces the intermediate portion 31 of the current detection busbar 30, is formed in a shape that conforms to the outer circumferential surface of the intermediate portion 31 of the current detection busbar 30. Also, an external side face of the core supporting portion 43, which is a face that faces the magnetic core 10, is formed in a shape that conforms to the inner circumferential surface of the magnetic core 10 that forms the hole portion 11.

As shown in FIG. 5, the core supporting portion 43 is inserted in the hole portion 11 of the magnetic core 10 and supports the magnetic core 10. The core supporting portion 43 also supports the magnetic core 10 in a state in which the core supporting portion 43 is sandwiched between the magnetic core 10 and the intermediate portion 31 of the current detection busbar 30.

Moreover, three or more projecting portions 431 that are plastically deformable under the pressure applied by the magnetic core 10 and the intermediate portion 31 of the current detection busbar 30 sandwiching the projecting portions 431—are formed on the internal side face of the core supporting portion 43. Each of the projecting portions 431 is formed so as to extend in the current flow direction (X-axis direction), that is, the direction in which the current detection busbar 30 penetrates the busbar holes 45.

Moreover, the projecting portions 431 are formed at three or more positions on the internal side face of the core supporting portion 43 so as to sandwich the intermediate portion 31 of the current detection busbar 30. When the three or more projecting portions 431 are provided, the core supporting portion 43 stably supports the magnetic core 10 with the projecting portions 431. In the example shown in FIG. 5, two pairs of projecting portions 431 are provided, the projecting portions 431 of each pair facing each other across the intermediate portion 31 of the current detection busbar 30.

In the casing main body 41, in a state prior to the insertion of the intermediate portion 31 of the current detection busbar 30 into the busbar hole 45—that is, in a natural state—the core supporting portion 43, which supports the magnetic core 10, is provided in a state in which a little gap (or play) is created between the core supporting portion 43 and the magnetic core 10. Then, in a state in which the core supporting portion 43 is inserted between the magnetic core 10 and the current detection busbar 30 in the hole portion 11 of the magnetic core 10, the core supporting portion 43 elastically deforms outward under the pressure applied by the current detection busbar 30, and comes into close contact with the inner circumferential surface of the magnetic core 10. The current detection busbar 30 functions as a wedge for bringing the core supporting portion 43 into close contact with the magnetic core 10.

In the current detector 1 that has the above-described structure, a phenomenon in which the magnetic core 10 and the core supporting portion 43 repeatedly collide with each other in an environment in which they are subjected to vibrations of the vehicle or the like does not occur, and the magnetic core 10 and the core supporting portion 43 are unlikely to wear down due to the vibrations. Consequently, the current detector 1 is more durable than other current detectors in which a gap is formed between the magnetic core 10 and a portion that supports the magnetic core 10.

Also, since the internal side face of the core supporting portion 43 have the projecting portions 431 made of resin, the dimensional tolerances of the current detection busbar 30, the core supporting portion 43, and the magnetic core 10 are accommodated by the extent of plastic deformation of the projecting portions 431. Thus, it is possible to avoid a situation in which the core supporting portion 43 cannot be inserted in the gap between the magnetic core 10 and the current detection busbar 30 due to the dimensional tolerances.

Meanwhile, the clement supporting portion 44 is formed in one piece so as to surround the perimeter of the Hall element 20 that is disposed in the gap portion 12 of the magnetic core 10. The space surrounded by the element supporting portion 44 is the space to which the main body portion of the Hall element 20 is fitted, in the gap portion 12 of the magnetic core 10. When the main body portion of the Hall element 20 is fitted to the internal space of the element supporting portion 44, the element supporting portion 44 supports the Hall element 20 in a predetermined position within the gap portion 12.

Also, in this embodiment, the element supporting portion 44 is formed in one piece with the core supporting portion 43. This reduces deviations of the relative positions of the core supporting portion 43 and the element supporting portion 44, resulting in an increase in the accuracy of positioning the magnetic core 10 and the Hall element 20 relative to each other.

<Procedures for Attaching Current Detection Busbar>

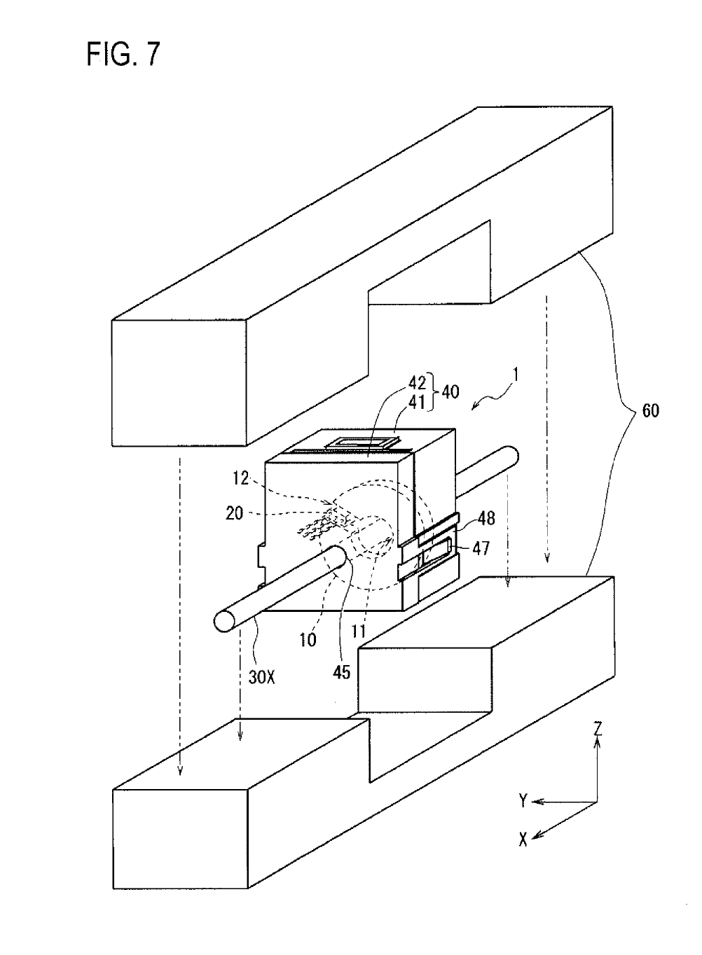

Hereinafter, the procedures for attaching the current detection busbar 30 to the insulating casing 40 will be described with reference to FIG. 7. FIG. 7 is a perspective view of a step of performing press working of the two end portions of the current detection busbar 30.

In the current detector 1, the terminal portions 32 of the current detection busbar 30 are formed so as to be wider than the intermediate portion 31 of the current detection busbar 30. Furthermore, the busbar holes 45 of the insulating casing 40 are formed in a shape that conforms to the contour of the intermediate portion 31 of the current detection busbar 30. Thus, it is not possible to pass the current detection busbar 30 in which the two flat plate-like terminal portions 32 have been formed through the busbar holes 45 of the insulating casing 40.

FIG. 7 is a perspective view illustrating a step of performing press working of a rod-shaped metal member 30X that mainly constitutes the current detection busbar 30. As shown in FIG. 7, the member that mainly constitutes the current detection busbar 30 is the rod-shaped metal member 30X.

The current detection busbar 30 is a member that is obtained by shaping both end portions of the rod-shaped metal member 30X that penetrates the busbar holes 45 of the insulating casing 40 and the hole portion 11 of the magnetic core 10 by press working—the two end portions occupying certain ranges from the respective ends of the metal member 30X—so that the two end portions are wider than an intermediate portion between the two end portions. In this embodiment, since the intermediate portion 31 of the current detection busbar 30 has a cylindrical shape, the rod-shaped metal member 30X has a cylindrical shape.

As shown in FIG. 7, in the manufacturing process of the current detector 1, prior to shaping of the current detection busbar 30, the magnetic core 10, the Hall element 20, and the electronic circuit board 50 are assembled within the insulating casing 40. Thus, the magnetic core 10, the Hall element 20, and the electronic circuit board 50 are supported in a fixed positional relationship within the insulating casing 40.

After that, the rod-shaped metal member 30X, which mainly constitutes the current detection busbar 30, is allowed to pass through the busbar holes 45 of the insulating casing 40. Thus, the rod-shaped metal member 30X penetrates the busbar holes 45 of the insulating casing 40 and the hole portion 11 of the magnetic core 10 that is housed in the insulating casing 40.

Furthermore, the two end portions of the rod-shaped metal member 30X penetrating the insulating casing 40 are shaped into a flat plate-like shape by press working using a pressing machine 60. Thus, the current detection busbar 30 penetrating the busbar holes 45 of the insulating casing 40 and the hole portion 11 of the magnetic core 10 that is housed in the insulating casing 40 is obtained.

Note that the screw through holes 32z of the terminal portions 32 are formed by forming holes in the portions that have been shaped into a flat plate-like shape by press working.

It also is conceivable that only one end portion of the rod-shaped metal member 30X is shaped into a flat plate-like shape first. The other end portion of the rod-shaped metal member 30X is then allowed to pass through the busbar holes 45 of the insulating casing 40. Thereafter, the other end portion is shaped into a flat plate-like shape.

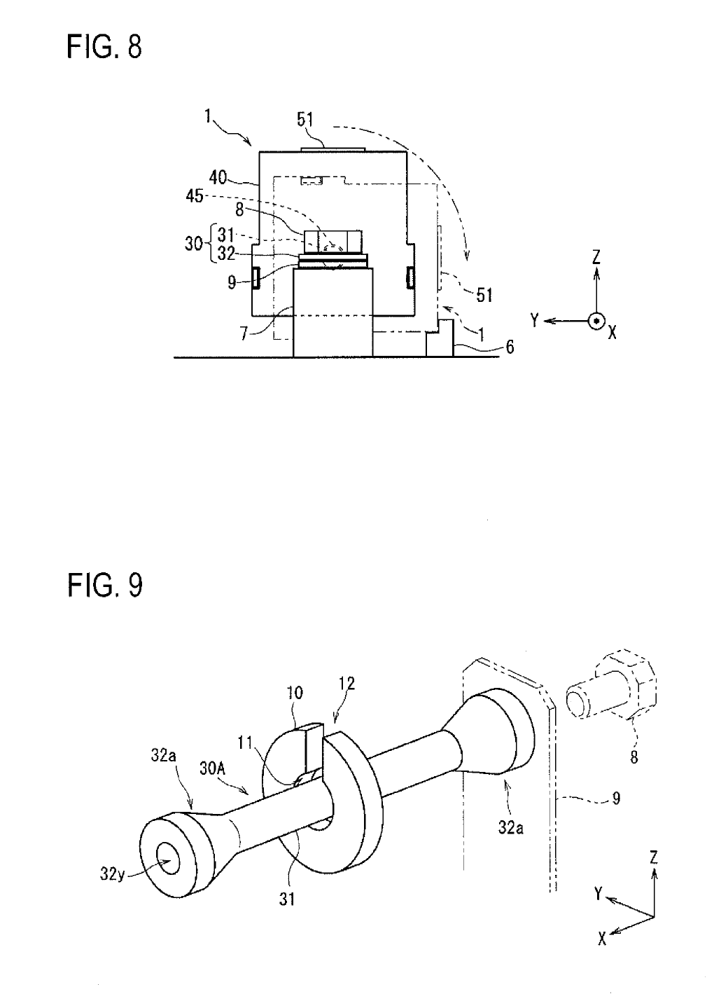

FIG. 8 is a front view of the current detector 1 that is fixed to a terminal block 7. As shown in FIG. 8, the two terminal portions 32 of the current detection busbar 30 of the current detector 1 are joined to other flat plate-like upstream and downstream busbars 9 with screws 8 such as bolts and also fixed to the terminal block 7.

In the current detector 1, the intermediate portion 31 of the current detection busbar 30 has a cylindrical shape, and the busbar holes 45 of the insulating casing 40 have a circular shape. Thus, it is possible to rotate the insulating casing 40 around the intermediate portion 31 of the current detection busbar 30.

As shown in FIG. 8, in a state in which the two terminal portions 32 of the current detection busbar 30 are fixed to the other upstream and downstream busbars 9, the overall orientation of the insulating casing 40 and the constitutional elements that are supported by the insulating casing 40—except the current detection busbar 30—can be changed. Thus, after a connector of a connection target wire has been connected to the connector 51 from a specific direction, the orientation of the connector 51 can be changed so that the connection target wire extends along a predetermined wiring path. Note that in FIG. 8, the insulating casing 40 after the orientation thereof has been changed is shown by a phantom line (chain double-dashed line).

However, in order to prevent rotation of the current detector 1 that has been installed, as shown in FIG. 8, it is necessary that a rotation stopper 6 for fixing the orientation of the current detector 1 is provided at a location where the current detector 1 is installed.

<Current Detection Busbar According to Modification>

Next, a current detection busbar 30A according to a modification that is applicable to the current detector 1 will be described with reference to FIG. 9. FIG. 9 is a perspective view of the current detection busbar 30A and the magnetic core 10.

As in the case of the current detection busbar 30 shown in FIGS. 1 and 2, the current detection busbar 30A is composed of a member that is obtained by shaping the two end portions of the rod-shaped metal member 30X that penetrates the hole portion 11 of the magnetic core 10 so that the two end portions are wider than the intermediate portion 31. Also, the two shaped end portions form the two terminal portions 32a that are to be joined to connection ends of the other upstream and downstream busbars 9.

However, the two terminal portions 32a of the current detection busbar 30A do not have a flat plate-like shape, but the portions that are shaped by upsetting the two end portions of the rod-shaped metal member 30X so that those end portions are thicker than the intermediate portion 31. In addition, the two terminal portions 32a of the current detection busbar 30A have screw holes 32y into which the screws 8 for joining the terminal portions 32a to the connection ends of the other upstream and downstream busbars 9 are screwed.

The terminal portions 32a of the current detection busbar 30A are formed by upsetting the end portions of the rod-shaped metal member 30X using a jig in which a mold for shaping the terminal portions 32a is formed, a pressing machine, and the like. The end portions of the rod-shaped metal member 30X that is held by the jig are pressed by the pressing machine or the like along the axis of the rod-shaped metal member 30X. Thus, the end portions of the rod-shaped metal member 30X are processed so as to be thicker than the other portions. At that time, at least one of the two ends of the rod-shaped metal member 30X is subjected to upsetting after the rod-shaped metal member 30X has been inserted into the busbar holes 45 of the insulating casing 40.

The current detection busbar 30A shown in FIG. 9 may also be applied to the current detector 1 instead of the current detection busbar 30.

<Effects>

In the current detector 1, the two end portions of the current detection busbar 30 or 30A serve as the terminal portions 32 or 32a that are respectively joined to the connection ends of the other upstream and downstream busbars 9 in the current transmission path. Also, the busbar holes 45 of the insulating casing 40 are formed in a shape that conforms to the contour of the intermediate portion 31 of the current detection busbar 30 or 30A. Furthermore, the two terminal portions 32 or 32a of the current detection busbar 30 or 30A are formed in conformity with the width of the other upstream and downstream busbars 9 so that the width (or thickness) of the two terminal portions 32 or 32a is larger than the width (or thickness) of the intermediate portion 31 that penetrates the busbar holes 45 of the insulating casing 40 and the hole portion 11 of the magnetic core 10.

At least one of the two terminal portions 32 or 32a of the current detection busbar 30 or 30A is obtained by shaping the corresponding end portion of the rod-shaped metal member 30X after passing the rod-shaped metal member 30X through the busbar holes 45 of the insulating casing 40 and the hole portion 11 of the magnetic core 10.

Accordingly, with the current detector 1, it is possible to downsize the current detector 1 by employing a magnetic core 10 that is relatively small in relation to the size of the other upstream and downstream busbars 9 in the current transmission path.

Moreover, in the current detection busbar 30, the intermediate portion 31 has a rod-like shape in which the ratio of the width to the thickness is 1 or approximately 1. Thus, the intermediate portion 31 can be formed so as to have a larger cross-sectional area than that of a flat plate-like busbar, with the restriction that the maximum width of the intermediate portion 31 is smaller than the width of the hole portion 11 of the magnetic core 10. Therefore, even if a relatively small magnetic core 10 is employed, it is possible to prevent the current detection busbar 30 from excessively generating heat.

It also is conceivable to use a current detector according to a reference example that will be described below as the current detector including the current detection busbar 30 in which the two terminal portions 32 are formed. In the current detector according to the reference example, the busbar holes of the insulating casing 40 are formed in a shape that conforms to the contour of the terminal portions 32 of the current detection busbar 30. Those portions of the current detection busbar 30 that correspond to the two terminal portions 32 penetrate the respective busbar holes of the insulating casing 40. In this case, the insulating casing 40 houses the entire intermediate portion 31 of the current detection busbar 30, the magnetic core 10, and the Hall element 20.

However, if the terminal portions 32 of the current detection busbar 30 have a flat plate-like shape, the busbar holes of the reference example will be through holes in the form of a narrow slot. On the other hand, the busbar holes 45 of the current detector 1 are through holes in which the ratio of the longitudinal dimension to the lateral dimension is 1 or approximately 1. Generally, with respect to resin molded members, a through hole in which the ratio of the longitudinal dimension to the lateral dimension is 1 or approximately 1 can be molded with higher accuracy than a through hole in the form of a narrow slot.

Therefore, when compared with a through hole in the form of a narrow slot, a through hole in which the ratio of the longitudinal dimension to the lateral dimension is 1 or approximately 1 can be molded so as to have dimensions that are closer to the dimensions of the contour of the current detection busbar, or in other words, dimensions with little play. Accordingly, if the terminal portions 32 of the current detection busbar 30 have a flat plate-like shape, the area of a gap between an edge portion of each busbar hole of the insulating casing 40 and the current detection busbar 30 in the case where the current detector 1 is employed is smaller than that in the case where the current detector according to the reference example is employed. As a result, a dustproof effect of preventing the entry of dust into the insulating casing 40 increases.

Also, with respect to resin molded members, an edge portion of a through hole in the form of a narrow slot is likely to crack due to stress concentration. On the other hand, with respect to resin molded members, a portion in which a through hole in which the ratio of the longitudinal dimension to the lateral dimension is 1 or approximately 1 is formed is unlikely to crack due to stress concentration. Accordingly, if the terminal portions 32 of the current detection busbar 30 have a flat plate-like shape, the casing is more unlikely to crack due to stress concentration in the case where the current detector 1 is employed than in the case where the current detector according to the reference example is employed.

Also, in the current detector 1, the core supporting portion 43 supports the magnetic core 10 and the current detection busbar 30 in a state in which the core supporting portion 43 is sandwiched between the magnetic core 10 and the current detection busbar 30. In this case, even if the core supporting portion 43 is provided in a state in which a little gap (play) is created between the core supporting portion 43 and the magnetic core 10, when the core supporting portion 43 is inserted between the magnetic core 10 and the intermediate portion 31 of the current detection busbar 30 in the hole portion 11 of the magnetic core 10, the core supporting portion 43 elastically deforms under the pressure applied by the current detection busbar 30 and comes into close contact with the inner circumferential surface of the magnetic core 10. Therefore, a phenomenon in which the magnetic core 10 and the core supporting portion 43 repeatedly collide with each other in an environment in which they are subjected to vibrations of the vehicle or the like does not occur, and the magnetic core 10 and the core supporting portion 43 are unlikely to wear down due to the vibrations.

Also, the projecting portions 431 that are formed on the core supporting portion 43 plastically deform under the pressure applied by the magnetic core 10 and the intermediate portion 31 of the current detection busbar 30 sandwiching the projecting portions 431. Thus, the dimensional tolerances of the current detection busbar 30, the core supporting portion 43, and the magnetic core 10 are accommodated by the extent of the plastic deformation of the projecting portions 431. Therefore, it is possible to avoid a situation in which the core supporting portion 43 cannot be inserted into the gap between the magnetic core 10 and the current detection busbar 30 due to the dimensional tolerances.

Also, since the contour shape of the intermediate portion 31 of the current detection busbar 30 is homothetically similar to the contour shape of the hole portion 11 of the magnetic core 10, the gap between the current detection busbar 30 and the magnetic core 10 can be reduced. Consequently, it is possible to downsize the current detector by employing a smaller magnetic core 10.

Also, since the intermediate portion 31 of the current detection busbar 30 has a cylindrical shape, and the busbar holes 45 have a circular shape, it is possible to rotate the insulating casing 40 around the intermediate portion 31 of the current detection busbar 30. Thus, in a state in which the two terminal portions 32 of the current detection busbar 30 are fixed to the other upstream and downstream busbars 9, the overall orientation of the insulating casing 40 and the constitutional elements supported by the insulating casing 40 except the current detection busbar 30 can be changed. The degree of freedom of attachment of the current detector 1 is increased.

Also, the terminal portions 32 of the current detection busbar 30 can be easily made by, for example, press working or upsetting of the rod-shaped metal member 30X.

<Others>

In the above-described current detector 1, the three or more projecting portions 431 are formed on the internal side face of the core supporting portion 43. However, it also is conceivable that three or more similar projecting portions 431 are formed on the external side face of the core supporting portion 43. The projecting portions 431 in that case abut against the inner circumferential surface of the magnetic core 10 and plastically deform under the pressure applied by the magnetic core 10 and the current detection busbar 30 sandwiching the projecting portions 431.

Also, in the above-described embodiment, the intermediate portion 31 of the current detection busbar 30 has a cylindrical shape. However, the intermediate portion 31 of the current detection busbar 30 may also have other shapes. For example, it is conceivable that the intermediate portion 31 of the current detection busbar 30 has the shape of a prism. In this case, the internal side face of the core supporting portion 43 and the busbar holes 45 of the insulating casing 40 are formed in a polygonal shape that conforms to the contour of the intermediate portion 31 of the current detection busbar 30.

In the case where the contour shape of the intermediate portion 31 of the current detection busbar 30 and the shape of the busbar holes 45 are not circular, the insulating casing 40 cannot be rotated around the intermediate portion 31 of the current detection busbar 30. Therefore, in the case where there is no need to rotate the insulating casing 40 after the current detection busbar 30 has been fixed to the other upstream and downstream busbars 9, it is preferable to employ the current detection busbar 30 in which the intermediate portion 31 does not have a cylindrical shape.

Moreover, in the current detector 1, the magnetic core 10 is formed so as to have a circular ring-like shape in conjunction with the gap portion 12. However, it also is conceivable that the magnetic core 10 is formed in other shapes. For example, it is conceivable that the magnetic core 10 has a polygonal ring-like shape in conjunction with the gap portion 12, and the contour shape (cross-sectional shape) of the intermediate portion 31 of the current detection busbar 30 is a polygon that is homothetically similar to the polygon defined by the hole portion 11 of the magnetic core 10. In this case, the external side face of the core supporting portion 43 is formed in a polygonal shape that is homothetically similar to the contour shape of the hole portion 11 of the magnetic core 10.

Moreover, in the current detector 1, it also is conceivable that the two terminal portions 32 of the current detection busbar 30 have mutually different shapes. For example, it is conceivable that one end portion of the current detection busbar 30 is the flat plate-like terminal portion 32, and the other end portion is the terminal portion 32a that is formed so as to be thick by upsetting.

1. A current detector for detecting a current that flows through a busbar, the current detector comprising:
a magnetic core that is formed in one piece so as to surround a hole portion, two ends of the magnetic core facing each other across a gap portion;
a magneto-electric conversion element that is disposed in the gap portion and detects a magnetic flux that changes in accordance with a current that passes through the hole portion of the magnetic core;
a current detection busbar that is composed of a member obtained by shaping both end portions of a rod-shaped conductor that penetrates the hole portion of the magnetic core;
the two end portions occupying certain ranges from respective ends of the rod-shaped conductor, so that the two end portions are wider than an intermediate portion between the two end portions;
the two shaped end portions forming two terminal portions that are to be joined to an upstream connection end and a downstream connection end, respectively, in a current transmission path; and
a casing that supports and houses a portion of the intermediate portion of the current detection busbar, the magnetic core, and the magneto-electric conversion element in a fixed positional relationship and has busbar holes that are formed in a shape conforming to a contour of the intermediate portion of the current detection busbar and with a smaller width than a width of the terminal portions and penetrated by the intermediate portion.

2. The current detector according to claim 1, wherein the casing comprises a core supporting portion that is formed on an internal side face of the casing, protruding from an edge portion of the busbar hole, the core supporting portion supporting the magnetic core by being inserted in the hole portion of the magnetic core and supporting the current detection busbar in a state in which the core supporting portion is sandwiched between the magnetic core and the intermediate portion of the current detection busbar.

3. The current detector according to claim 2, wherein a projecting portion is formed on a face of the core supporting portion that faces the current detection busbar or the magnetic core, the projecting portion being plastically deformable under pressure applied by the magnetic core and the intermediate portion of the current detection busbar sandwiching the projecting portion.

4. The current detector according to claim 1, wherein the intermediate portion of the current detection busbar has a contour shape that is homothetically similar to a contour shape of the hole portion of the magnetic core.

5. The current detector according to claim 1, wherein the intermediate portion of the current detection busbar has a cylindrical shape, and the busbar holes of the casing have a circular shape.

6. The current detector according to claim 1, wherein the terminal portions of the current detection busbar are portions that are shaped by performing press working of the two end portions of the rod-shaped metal member so that the two end portions have a flat plate-like shape that is wider than other portions of the rod-shaped metal member.

7. The current detector according to claim 1, wherein the terminal portions of the current detection busbar are portions that are shaped by performing upsetting of the two end portions of the rod-shaped metal member so that the two end portions are thicker than other portions of the rod-shaped metal member.

8. The current detector according to claim 2, wherein the intermediate portion of the current detection busbar has a contour shape that is homothetically similar to a contour shape of the hole portion of the magnetic core.

9. The current detector according to claim 3, wherein the intermediate portion of the current detection busbar has a contour shape that is homothetically similar to a contour shape of the hole portion of the magnetic core.

10. The current detector according to claim 2, wherein the inter mediate portion of the current detection busbar has a cylindrical shape, and the busbar holes of the casing have a circular shape.

11. The current detector according to claim 3, wherein the intermediate portion of the current detection busbar has a cylindrical shape, and the busbar holes of the casing have a circular shape.

12. The current detector according to claim 4, wherein the intermediate portion of the current detection busbar has a cylindrical shape, and the busbar holes of the casing have a circular shape.

13. The current detector according to claim 2, wherein the terminal portions of the current detection busbar are portions that are shaped by performing press working of the two end portions of the rod-shaped metal member so that the two end portions have a flat plate-like shape that is wider than other portions of the rod-shaped metal member.

14. The current detector according to claim 3, wherein the terminal portions of the current detection busbar are portions that are shaped by performing press working of the two end portions of the rod-shaped metal member so that the two end portions have a flat plate-like shape that is wider than other portions of the rod-shaped metal member.

15. The current detector according to claim 4, wherein the terminal portions of the current detection busbar are portions that are shaped by performing press working of the two end portions of the rod-shaped metal member so that the two end portions have a flat plate-like shape that is wider than other portions of the rod-shaped metal member.

16. The current detector according to claim 5, wherein the terminal portions of the current detection busbar are portions that are shaped by performing press working of the two end portions of the rod-shaped metal member so that the two end portions have a flat plate-like shape that is wider than other portions of the rod-shaped metal member.

17. The current detector according to claim 2, wherein the terminal portions of the current detection busbar are portions that are shaped by performing upsetting of the two end portions of the rod-shaped metal member so that the two end portions are thicker than other portions of the rod-shaped metal member.

18. The current detector according to claim 3, wherein the terminal portions of the current detection busbar are portions that are shaped by performing upsetting of the two end portions of the rod-shaped metal member so that the two end portions are thicker than other portions of the rod-shaped metal member.

19. The current detector according to claim 4, wherein the terminal portions of the current detection busbar are portions that are shaped by performing upsetting of the two end portions of the rod-shaped metal member so that the two end portions are thicker than other portions of the rod-shaped metal member.

20. The current detector according to claim 5, wherein the terminal portions of the current detection busbar are portions that are shaped by performing upsetting of the two end portions of the rod-shaped metal member so that the two end portions are thicker than other portions of the rod-shaped metal member.
